(19) United States
(12) Patent Application Publication
(10) Pub. No.: US 2023/0197154 A1
(43) Pub. Date: Jun. 22, 2023

(54) STATIC RANDOM-ACCESS MEMORY (SRAM) CELL FOR HIGH-SPEED CONTENT-ADDRESSABLE MEMORY AND IN-MEMORY BOOLEAN LOGIC OPERATION

(71) Applicant: SHANGHAITECH UNIVERSITY, Shanghai (CN)

(72) Inventors: Jian CHEN, Shanghai (CN); Yajun HA, Shanghai (CN)

(73) Assignee: SHANGHAITECH UNIVERSITY, Shanghai (CN)

(21) Appl. No.: 17/802,968

(22) PCT Filed: Sep. 22, 2021
(86) PCT No.: PCT/CN2021/119515

§ 371 Date: Aug. 29, 2022

(30) Foreign Application Priority Data
May 13, 2021 (CN) 202110520255.0

(51) Int. Cl. G11C 15/04

(52) U.S. Cl. CPC G11C 15/04

(57) ABSTRACT

A static random-access memory (SRAM) cell for high-speed content-addressable memory (CAM) and in-memory Boolean logic operations includes a standard 6T-SRAM and two additional PMOS access transistors, where read word lines of the two positive-channel metal oxide semiconductor (PMOS) access transistors P1 and P2 are RWLR and RWLL respectively, and under the control thereof, a differential read port RBL/R̅B̅L̅ is formed. The SRAM cell is suitable for multi-row address selection, and typically applied to in-memory high-speed CAM and in-memory Boolean logic operations. Due to PMOS device characteristics, the structure design of the SRAM cell can avoid read disturbance generated by an in-memory SRAM, and ensure that the SRAM can perform in-memory CAM and in-memory Boolean logic operations stably at a high speed. In addition, this SRAM-based IMC solution supports commercial CMOS technology, and has an opportunity to leverage a large number of existing on-chip SRAM caches.

### CROSS REFERENCE TO THE RELATED APPLICATIONS

This application is the national phase entry of International Application No. PCT/CN2021/119515, filed on Sep. 22, 2021, which is based upon and claims priority to Chinese Patent Application No. 202110520255.0, filed on May 13, 2021, the entire contents of which are incorporated herein by reference.

### TECHNICAL FIELD

The present disclosure relates to an electronic device design technology, and in particular, to a static random-access memory (SRAM) cell for high-speed content-addressable memory (CAM) and in-memory Boolean logic operations.

### BACKGROUND

The surge of data-intensive applications such as artificial intelligence poses an ever-increasing demand for high-throughput and energy-efficient computing architectures. However, in the traditional von Neumann architecture, data needs to be transferred back and forth between a memory and a computing unit, leading to a limited data throughput and large energy overheads [1]. To tackle this challenge, an in-memory computing (IMC) architecture has been proposed to address the bottleneck of the von Neumann architecture by reducing data transmissions and directly performing computation inside the memory. Recently, different levels of memory have been explored, including SRAM, dynamic random access memory (DRAM), resistive random access memory (RRAM), spin-transfer torque magnetic random access memory (STT-MRAM), and flash memory (Flash), to implement an efficient IMC system.

Many IMC SRAMs designed with different cell structures have been proposed, such as 6T [2], standard 8T [3], 9T [4], and 10T [5]. By using massive parallel bit lines, the SRAM is capable of processing high-throughput and efficient logic/arithmetic/matrix computations. In [3], an analog-based IMC SARM has been proposed to perform multiply-and-accumulate (MAC)/dot-product computations, but it only supports specific fault-tolerant applications such as a convolutional neural network (CNN). In addition, these designs require expensive digital-to-analog converters (DACs) and analog-to-digital converters (ADCs) to convert analog voltages. Another promising digital-based IMC SRAM can perform precise bit-wise computations and has a wider range of application. In [2], basic CAM operations and Boolean logic operations have been implemented in 6T/8T SRAMs by activating a plurality of word lines. Through basic Boolean operations, addition/multiplication has been implemented in [6], and complex applications such as advanced encryption standard (AES) and CNN algorithms have been successfully executed.

However, when a plurality of word lines are activated simultaneously, both the analog-based IMC SRAM and the digital-based IMC SRAM encounter read disturbance due to shared read and write paths, which may corrupt stored data. To address the read disturbance, a hierarchical 6T SRAM design [7] and an interleaved structure [8] are proposed to avoid the read disturbance at the architectural level, but they both have rigid restrictions on data allocation and thus are not suitable for CAM applications. Other auxiliary schemes for the 6T SRAM, including weak word line drive [2] and interleaved word line activation [4], severely reduce the access speed. The standard 8T SRAM has also been explored to achieve IMC without read disturbance [9], but it causes performance degradation due to a low read margin. The 9T [4] and 10T [5] SRAMs with decoupling differential ports are reliable, but they bring large area overheads. In general, the previous solutions designed to solve the read disturbance problem of the IMC SRAM all lead to a reduction in speed or additional overheads in area.

Documents for reference are as follows:
[1] M. Horowitz, “1.1 computing's energy problem (and what we can do about it),” in 2014 IEEE Int. Solid-State Circuits Conference Digest of Technical Papers (ISSCC). IEEE, February 2014, pp. 1.
[2] S. Jeloka, N. B. Akesh, D. Sylvester, and D. Blaauw, “A 28 nm configurable memory (TCAM/BCAM/SRAM) using push-rule 6t bit cell enabling logic-in-memory,” IEEE J. Solid-State Circuits, vol. 51, no. 4, pp. 1009-1021, April 2016.
[3] A. Jaiswal, I. Chakraborty, A. Agrawal, and K. Roy, “8T SRAM cell as a multibit dot-product engine for beyond von Neumann computing,” IEEE Trans. Very Large Scale Integr. (VLSI) Syst., vol. 27, no. 11, pp. 2556-2567, November 2019.
[4] A. Agrawal, A. Jaiswal, C. Lee, and K. Roy, “X-SRAM: Enabling in-memory Boolean computations in CMOS static random access memories,” IEEE Trans. Circuits Syst. I, Reg. Papers, vol. 65, no. 12, pp. 4219-4232, December 2018.
[5] Y. Zhang, L. Xu, Q. Dong, J. Wang, D. Blaauw, and D. Sylvester, “Recryptor: A reconfigurable cryptographic cortex-MO processor with in-memory and near-memory computing for IoT security,” IEEE J. Solid-State Circuits, vol. 53, no. 4, pp. 995-1005, April 2018.
[6] J. Wang, X. Wang, C. Eckert, A. Subramaniyan, R. Daset al., “A 28-nm compute SRAM with bit-Serial logic/arithmetic operations for pro-grammable in-memory vector computing,” IEEE J. Solid-State Circuits, January 2020.
[7] W. Simon, J. Galicia, A. Levisse, M. Zapater, and D. Atienza, “A fast, reliable and wide-voltage-range in-memory computing architecture,” in Proc. 56th ACM/IEEE Annu. Design Autom. Conf. (DAC), June 2019, pp. 1-6.
[8] A. Jaiswal, A. Agrawal, M. F. Ali, S. Sharmin, and K. Roy, “i-SRAM: Interleaved Wordlines for Vector Boolean Operations Using SRAMs,” IEEE Trans. Circuits Syst. I, Reg. Papers, vol. 67, no. 12, pp. 4651-4659, 2020.
[9] Z. Lin, H. Zhan, X. Li, C. Peng, W. Lu, X. Wu, and J. Chen, “In-Memory Computing With Double Word Lines and Three Read Ports for Four Operands,” IEEE Trans. Very Large Scale Integr. (VLSI) Syst., vol. 28, no. 5, pp. 1316-1320, May.

### SUMMARY

In view of the read disturbance problem of existing high-speed SRAMs, a SRAM cell for high-speed CAM and in-memory Boolean logic operations is proposed, to mitigate the read disturbance problem of an IMC SRAM and ensure stable and high-speed execution of the SRAM, in-memory CAM, and in-memory logic operations.

The technical solution of the present disclosure is as follows: A SRAM cell for high-speed CAM and in-memory Boolean logic operations includes a standard 6T-SRAM and two additional PMOS access transistors, where read word lines of the two PMOS access transistors P1 and P2 are RWLR and RWLL respectively, and under the control of the two PMOS access transistors, a differential read port RBL/R̅B̅L̅ is formed.

Preferably, work states of NMOS access transistors N1 and N2 of the standard 6T-SRAM and the two additional PMOS access transistors P1 and P2 are as follows:

| | | |
|---|---|---|
| Memory Operations | CAM- | Logic- |

| | Hold | Write | Read | Operations | Operations |
|---|---|---|---|---|---|
| N1, N2 | OFF | ON | ON | OFF | OFF |
| P1, P2 | OFF | OFF | OFF | ON | ON |

and a truth table corresponding to port voltages is as follows:

| | Memory Operations | | | CAM- | Logic- |
|---|---|---|---|---|---|
| | Hold | Write | Read | Operations | Operations |
| WL | GND | VDD | VDD | GND | GND |
| BL | VDD | VDD (write 1) | VDD | Floating | Floating |
| | | GND (write 0) | (precharge) | | |
| B̅L̅ | VDD | GND (write 1) | VDD | Floating | Floating |
| | | VDD (write 0) | (precharge) | | |
| RWLL | VDD | VDD | VDD | GND (search data 1) | GND |
| | | | | VDD (search data 0) | |
| RWLR | VDD | VDD | VDD | VDD (search data 1) | GND |
| | | | | GND (search data 0) | |
| RBL/R̅B̅L̅ | GND | Floating | Floating | GND (precharge) | GND (precharge) |

The beneficial effects of the present disclosure are as follows: The SRAM cell for high-speed CAM and in-memory Boolean logic operations in the present disclosure optimizes IMC of a SRAM, supports commercial CMOS technology, and has an opportunity to leverage the large number of existing on-chip SRAM caches.

### BRIEF DESCRIPTION OF THE DRAWINGS

FIG. 1 is a schematic structural diagram of an existing standard 8T SRAM cell.

FIG. 2 is a schematic structural diagram of an existing common dual-port 8T SRAM cell.

FIG. 3A is a schematic structural diagram of an 8T SRAM cell for high-speed CAM and IMC according to the present disclosure.

FIG. 3B is a timing diagram of an 8T SRAM cell for high-speed CAM and IMC according to the present disclosure.

FIG. 4 is a search example diagram of a binary content addressable memory (BCAM) on a 2×4 SRAM sub-array according to the present disclosure.

FIG. 5 is a search example diagram of a ternary content addressable memory (TCAM) on a 4×4 SRAM sub-array according to the present disclosure.

FIG. 6 is a diagram for realizing a composite in-memory Boolean logic operation with four operands by simultaneously using two read ports (RBL and BL) according to the present disclosure.

### DETAILED DESCRIPTION OF THE EMBODIMENTS

The present disclosure will be described in detail in conjunction with the accompanying drawings and specific embodiments. The embodiments are implemented on the premise of the technical solutions of the present disclosure. The following presents detailed implementations and specific operation processes. The protection scope of the present disclosure, however, is not limited to the following embodiments.

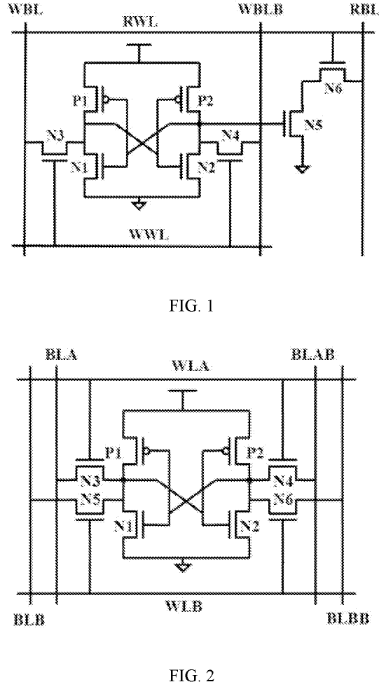

FIG. 1 is a schematic structural diagram of an existing standard 8T SRAM cell. The cell has two access ports: one is a read port (RBL) controlled by a read word line (RWL) and the other is a differential write port (WBL, WBLB) controlled by a write word line (WWL). In reference [9], a part of IMC operations are completed on the read port (RBL), and another part of the IMC operations are completed on the write port (WBL, WBLB). In this way, the cell implements in-memory CAM operations and Boolean logic operations. However, implementing computing on the write port (WBL, WBLB) also suffers from severe read disturbance problem as a 6T cell does. To suppress the read disturbance, WWL voltage is reduced, but performance is inevitably reduced. Moreover, because the read port (RBL) is single-ended in the cell, its read margin is smaller than that of a differential port. To ensure stability on the read port, the RBL requires a longer discharge time. Therefore, considering the foregoing two points, the standard 8T cell is difficult to implement high-speed IMC.

FIG. 2 is a schematic structural diagram of an existing common dual-port 8T SRAM cell. This cell adds another set of read and write ports on the basis of a single-port 6T SRAM cell. Because all of its access transistors (N3 to N6) are NMOS transistors, in the case of multi-row address selection, read disturbance is as severe as that of a 6T cell. Therefore, such structure is not suitable for IMC applications.

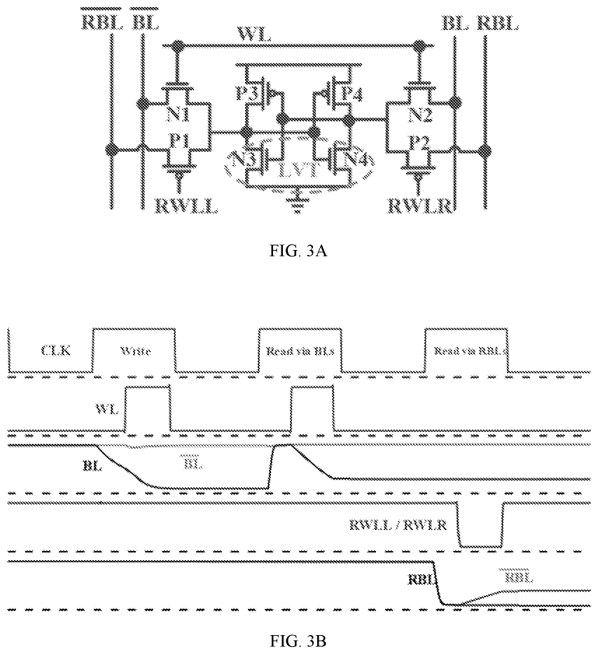

FIG. 3A is a schematic structural diagram of an 8T SRAM cell for high-speed CAM and IMC according to the present disclosure. The cell is an 8T SRAM that includes a standard 6T-SRAM and two additional PMOS access transistors (that is, P1 and P2). Although pull-down NMOS transistors (N3 and N4) are low V threshold (LVT) devices, the remaining transistors are regular V threshold (RVT) devices. To reduce read disturbances in the process of IMC access (that is, accessing multiple words simultaneously), PMOS transistors are used as access transistors of the SRAM cell. Because the PMOS transistors have a weaker driving capability than the NMOS transistors, miswrite operations caused by the read disturbance can be effectively reduced. In addition, the read bit line RBL connected to the PMOS access transistor is precharged to ground (GND), not to VDD as in the previous 6T SRAM. Because the PMOS transistor can transmit a strong “1” signal, the bit line can be rapidly charged to a target induced voltage. In this way, a high-speed IMC SRAM can be implemented.

The SRAM may be configured as a reliable high-speed BCAM or TCAM, or may be configured as a computational unit that performs Boolean logic functions. The 8T SRAM cell uses the 28 nm CMOS technology, with the same area as a standard 8T cell. As verified by post-simulation, a 16 Kb SRAM module operating at 2.7 GHz has a significantly higher speed than the previous designs.

FIG. 3B is a typical timing diagram of the proposed 8T SRAM. During a write cycle, only WL is selected to write data by pulling BL or B̅L̅ low. During a read cycle, although both ports (that is, BLs and RBLs) are accessible, their respective precharge and activation logics are different. The BLs are precharged to VDD like in the conventional 6T cell, while the RBLs connected to the PMOS access transistor are precharged to GND. Therefore, the traditional memory access is implemented by performing BL selection and discharging, while the successful memory access through the PMOS transistor is implementing by performing RBL selection and then charging.

With the additional read ports (that is, RBLs), the proposed 8T SRAM may be configured as a cell that performs SRAM, CAM, and in-memory logic operations. Table 1 is a detailed truth table for different operations. Table 2 lists work modes of the four access transistors. To perform the SRAM function, only WL is activated to perform a write or normal read operation. To perform the CAM function, the read word lines RWLLs and RWLRs of the PMOS access transistors P1 and P2 are configured to input search data. For example, if the search data is 1, the RWLL is pulled low to GND and the RWLR is pulled high to VDD. To perform Boolean logic operations, the read word lines RWLLs and RWLRs corresponding to P1 and P2 are selected.

TABLE 1

| | Memory Operations | | | CAM- | Logic- |
|---|---|---|---|---|---|
| | Hold | Write | Read | Operations | Operations |
| WL | GND | VDD | VDD | GND | GND |
| BL | VDD | VDD (write 1) | VDD | Floating | Floating |
| | | GND (write 0) | (precharge) | | |
| B̅L̅ | VDD | GND (write 1) | VDD | Floating | Floating |
| | | VDD (write 0) | (precharge) | | |
| RWLL | VDD | VDD | VDD | GND (search data 1) | GND |
| | | | | VDD (search data 0) | |
| RWLR | VDD | VDD | VDD | VDD (search data 1) | GND |
| | | | | GND (search data 0) | |
| RBL/R̅B̅L̅ | GND | Floating | Floating | GND (precharge) | GND (precharge) |

TABLE 2

| | | |
|---|---|---|
| Memory Operations | CAM- | Logic- |

| | Hold | Write | Read | Operations | Operations |
|---|---|---|---|---|---|
| N1, N2 | OFF | ON | ON | OFF | OFF |
| P1, P2 | OFF | OFF | OFF | ON | ON |

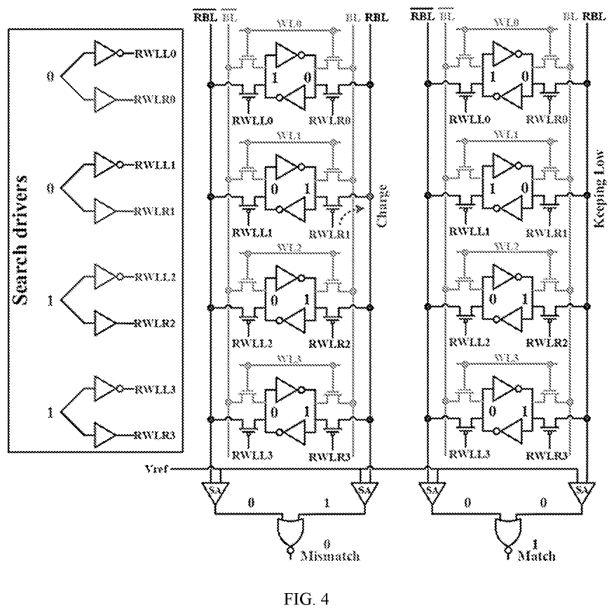

1) FIG. 4 shows an example of a BCAM on a 2×4 SRAM sub-array.

To support CAM operations, the RWLs are divided into RWLR and RWLL. The data to be searched is stored in columns, and compared with all columns by using word lines (that is, RWLRs or RWLLs) of driving rows. If input data is “0”, the RWLRs are at low level to turn on the right PMOS access transistor, and the RWLLs are at high level to turn off the left PMOS access transistor. When the input data is “1”, the case is the opposite.

For each column, a pair of single-ended sense amplifiers (SAs) are used to detect BL behavior, and a NOR gate connects the two SAs to generate a match or mismatch signal. In the case of a mismatch, as shown by the second bit in the first column in FIG. 4, the RBL is charged, and through comparison with an off-chip reference voltage (Vref), the SA connected to the charged RBL generates a logic “1”. Therefore, a NOR result of the two SAs is a logic “0”, indicating a mismatch. In the case of a match, as shown by the second column in FIG. 4, the RBLs are not charged and keep low. Then, the NOR result of the two SAs is a logic “1”, indicating a match.

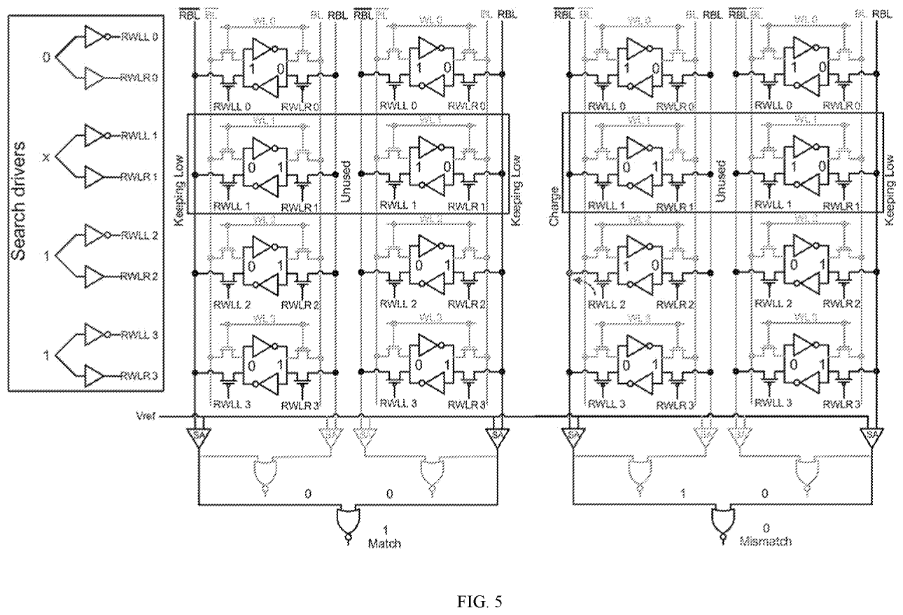

2) FIG. 5 shows an example of a TCAM search. Because the TCAM has three states, two bits are required to represent states 0, 1, and X (“don't care” state). Therefore, each word needs to be stored in two columns. The state X is represented by “10” enclosed in a box, and the states 0/1 are represented by “00” and “11”, respectively.

An induction scheme is the same as that of the BCAM. For each stored word, a search result can be generated by performing a NOR operation on outputs of the first SA and the fourth SA.

In the case of a match, the bit lines are not precharged, as shown by the first two columns in FIG. 5. In the case of a mismatch, as shown by the third bit in the last two columns in FIG. 5, the bit lines are charged, and the SA generates a logic “1”, such that the mismatch is detected.

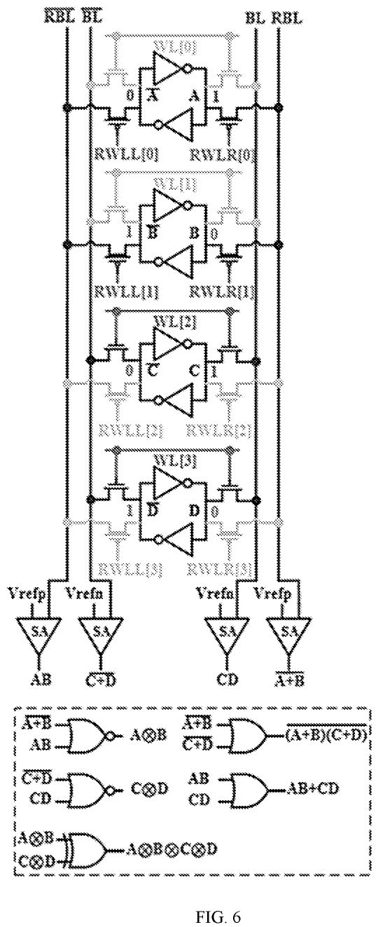

3) Multiple-operand compound logical operations are useful in many applications, such as Hamming codes. By utilizing the two read ports of the proposed 8T SRAM, four words can be accessed simultaneously in one cycle to perform a compound logical operation. As shown in FIG. 6, two RWLs are selected to perform one logical function in RBLs, and two WLs are also selected to perform another logical function in BLs. Through an additional logic gate, various compound logical operations can be implemented.

The above-mentioned examples only express several implementations of the present disclosure, and the descriptions thereof are relatively specific and detailed, but they should not be thereby interpreted as limiting the scope of the present disclosure. It should be noted that those of ordinary skill in the art can further make several variations and improvements without departing from the idea of the present disclosure, but such variations and improvements shall all fall within the protection scope of the present disclosure. Therefore, the protection scope of the present disclosure shall be subject to the appended claims.

What is claimed is:

1. A static random-access memory (SRAM) cell for high-speed content-addressable memory (CAM) and in-memory Boolean logic operations, comprising a standard 6T-SRAM and two additional positive-channel metal oxide semiconductor (PMOS) access transistors, wherein read word lines of the two additional PMOS access transistors P1 and P2 are RWLR and RWLL respectively, and under a control thereof, a differential read port RBL/R̅B̅L̅ is formed.

2. The SRAM cell for high-speed CAM and in-memory Boolean logic operations according to claim 1, wherein work states of negative channel-metal-oxide-semiconductor (NMOS) gated access transistors N1 and N2 of the standard 6T-SRAM and the two additional PMOS access transistors P1 and P2 are as follows:

| | | |
|---|---|---|
| Memory Operations | CAM- | Logic- |
| | Hold | Write | Read | Operations | Operations |
|---|---|---|---|---|---|
| N1, N2 | OFF | ON | ON | OFF | OFF |
| P1, P2 | OFF | OFF | OFF | ON | ON |

and a truth table corresponding to port voltages is as follows:

| | Memory Operations | | | CAM- | Logic- |
|---|---|---|---|---|---|
| | Hold | Write | Read | Operations | Operations |
| WL | GND | VDD | VDD | GND | GND |
| BL | VDD | VDD (write 1) | VDD | VDD | Floating |
| | | GND (write 0) | (precharge) | | |
| B̅L̅ | VDD | GND (write 1) | VDD | VDD | Floating |
| | | VDD (write 0) | (precharge) | | |
| RWLL | VDD | VDD | VDD | GND (search data 1) | GND |
| | | | | VDD (search data 0) | |
| RWLR | VDD | VDD | VDD | VDD (search data 1) | GND |
| | | | | GND (search data 0) | |
| RBL/R̅B̅L̅ | GND | Floating | Floating | GND (precharge) | GND (precharge) |
